(19) United States
(12) Patent Application Publication
(10) Pub. No.: US 2025/0273475 A1
(43) Pub. Date: Aug. 28, 2025

(54) QUASI-ATOMIC LAYER ETCHING OF SILICON NITRIDE ENHANCED BY REDUCED WAFER TEMPERATURE

(71) Applicant: California Institute of Technology, Pasadena, CA (US)

(72) Inventors: Daniel N Shanks, Pasadena, CA (US); Harold Frank Greer, Los Angeles, CA (US); Rania Ahmed, Pasadena, CA (US)

(73) Assignee: California Institute of Technology, Pasadena, CA (US)

(21) Appl. No.: 19/203,927

(22) Filed: May 9, 2025

Related U.S. Application Data
(63) Continuation-in-part of application No. 18/908,317, filed on Oct. 7, 2024.
(60) Provisional application No. 63/542,879, filed on Oct. 6, 2023.
(60) Provisional application No. 63/644,992, filed on May 9, 2024.

(51) Int. Cl. H01L 21/311; H01J 37/32

(52) U.S. Cl. CPC H01L 21/31116; H01J 37/32449; H01J 37/32724; H01J 37/321; H01J 2237/002; H01J 2237/334

(57) ABSTRACT

Illustrative embodiments describe a recipe using a low pressure (e.g., 20 mT SF₆) etch step, which can be achieved by most modern ICP Plasma systems. We find that in our modified etch recipe, the chemically modified layer can reach up to 20 nm in thickness, leading to an etch per cycle rate that is doubled compared to previous reports. We observed that at this lower pressure and at 10° C. wafer temperature, the SF₆ modified surface removal step loses its self-limiting aspect and etches material beyond the surface modified layer. However, we find that the self-limiting etch can be recovered by reducing the wafer temperature during the etch, with an added benefit of improved sidewall homogeneity and decreased surface roughness.

### CROSS REFERENCE TO RELATED APPLICATIONS

This application is a continuation in part under 35 USC 120 of U.S. Utility patent application Ser. No. 18/908,317, filed Oct. 7, 2024, by Harold Frank Greer, Jenni Solgaard, Ivy Chen, Austin Minnich, Alireza Marandi, and Ryoto Sekine, entitled “Quasi-Atomic Layer Etching of Mgo-Doped Lithium Niobate Using Sequential Exposures of H2 And Sf6 Plasma,” (CIT 9076) which application claims the benefit under 35 U.S.C. Section 119 (e) of U.S. Provisional Application No. 63/542,879, filed Oct. 6, 2023, by Harold Frank Greer, Jenni Solgaard, Ivy Chen, Austin Minnich, Alireza Marandi, and Ryoto Sekine, entitled “Quasi-Atomic Layer Etching of X-Cut Mgo-Doped Lithium Niobate Using Sequential Exposures of H2 And Sf6 Plasma,” (CIT 9076); and

This application claims the benefit under 35 U.S.C. Section 119 (e) of U.S. Provisional Application No. 63/644,992, filed May 9, 2024, by Daniel N Shanks, Harold Frank Greer, and Rania Ahmed, entitled “QUASI-ATOMIC LAYER ETCHING OF SILICON NITRIDE ENHANCED BY REDUCED WAFER TEMPERATURE,” (CIT 9007-P2);
all of which applications are incorporated by reference herein for all purposes.

### STATEMENT REGARDING FEDERALLY SPONSORED RESEARCH AND DEVELOPMENT

This invention was made with government support under Grant No. 80NMO0018D0004 awarded by NASA (JPL). The government has certain rights in the invention

### BACKGROUND OF THE INVENTION

### 1. Field of the Invention

The present disclosure relates to atomic layer etching of silicon nitride and devices and methods using the same.

### 2. Description of the Related Art

Atomic layer etching (ALE) is a cyclic, self-limiting dry etching process, involving alternating steps of surface modification and removal, which can allow for atomic level precision of etch depth.¹ This process allows for advanced lithography techniques such as self-aligned multiple patterning, and the reduction of feature sizes in nanofabrication, including transistor size.²⁻⁴ Due to the conformal self-limiting nature of the process, ALE will often have reduced surface roughness of etched material.^{5,6} Such precision is necessary for future technology nodes, and reduced loss in optical waveguides.

Silicon nitride (SiN) is a common dielectric material with a wide array of uses in nanofabrication and nanotechnology. It can be used as a dielectric spacer layer, a sacrificial mandrel or side wall layer in self aligned multiple patterning process⁷, or as a high index core material in waveguides and integrated photonic devices⁸. Silicon nitride with various ratios of silicon, nitrogen and hydrogen can have advantages over one another depending on the application⁹. Low stress silicon nitride is advantageous over stoichiometric silicon nitride for the growth of thicker waveguides, as the reduced stress prevents cracking,^{10,11} and can provide nonlinear effects for advanced photonic applications.¹² The processing method used to fabricate these waveguides can have significant effects on their propagation loss. For tightly confined waveguide modes in high index contrast platforms, scattering off of surface roughness created in the etch process can be a dominant source of loss.¹³⁻¹⁵

Atomic layer etching of silicon nitride is well studied, using both fluorocarbon chemistry,¹⁶⁻¹⁸ hydrogen plasma and HF wet etching,¹⁹, thermal atomic layer etching,²⁰ and hydrogen plasma surface modification followed by fluorine plasma removal.²¹⁻²⁴ In hydrogen/fluorine atomic layer etching, the silicon nitride is first exposed to a hydrogen plasma, where the surface is modified by hydrogen implantation in the nitride, creating a chemically modified-damaged layer ranging from 3-9 nm thick²¹. This chemically modified layer is then removed by the fluorinated plasma, which ideally stops material removal upon reaching the unmodified, pristine silicon nitride. The high hydrogen-implantation depth gives leads to significantly larger etch-per-cycle than conventional atomic layer etching recipes, opening practical applications to quickly etch thicker devices, such as waveguides. This established SiN ALE recipe works well in conventional RIE plasma etchers; however, the fluorinated plasma step runs at >1000 mT pressure, which is unachievable by some modern ICP RIE plasma systems. What is needed then, are improved methods for ALE of Silicon Nitride. The present disclosure satisfies this need.

### SUMMARY OF THE INVENTION

Atomic layer etching is a dry etching process using a dose step to modify a material's surface chemistry and an etch step to remove the modified surface layer. This method of etching has certain advantages over reactive ion etch due to its self-limiting etch process and reduced surface roughness.

In one embodiment, the present disclosure describes a cryogenic atomic layer etching recipe that reduces spontaneous (e.g., fluorine etching of silicon in Si-rich SiN), which can be used to improve side wall homogeneity, for example. Embodiments disclosed herein further expand upon an atomic layer etch recipe used to etch thin films of silicon nitride, which uses a H₂ plasma to modify the surface layer of the material and an SF₆ etch step to remove the modified surface. The results and parameter space of this recipe are explored at low wafer temperature, where we find a spontaneous isotropic SF₆ etching, which results in an enhancement in the self-limiting aspect of the etch process, as well as an improvement of the side wall homogeneity and decrease of etched surface roughness. The methods described herein can be useful for reducing optical loss in silicon nitride waveguides and other nanoscale devices made in silicon nitride.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1A. Quasi-atomic layer etching of silicon nitride in a conventional ICP RIE at 20 mT.

FIG. 1B. Example ALE reactor.

FIGS. 2A-2C. Atomic characterization of etched films. XPS gives absolute at % of Si, N (FIG. 2A) and O (FIG. 2B) content in films, while SIMS (FIG. 2C) gives the comparative H content between the two films.

FIGS. 3A-3B. Etch depth of the SiN after exposure to the hydrogen modification step and fluorinated plasma step, at 10° C. and −50° C., compared to the etch depth of the full ALE cycle for two different films (film 1 in FIG. 3A and film 2 in FIG. 3B).

FIGS. 4A-4D. Etch rate as a function of SF₆ step time and temperature, for SiN modified by 75 W, 5s of H₂ plasma (dashed lines) and pristine SiN (SF₆ step only, solid lines). Error bars determined by measuring the depth at various locations across the film.

FIG. 5A. Effect of H₂ bias power on etch characteristics of SiN at −50° C. DC Bias is varied by applying 0, 30, 75, and 150 W HF Bias in the etch recipe, maintaining a H₂ plasma time of 5s.

FIG. 5B. Effect of H₂ step time on etch rate per cycle using 75 W bias power, compared to sputtering of SiN by H₂ step alone (black dashed line). Blue dashed line shows the difference, corresponding to the thickness of the chemically modified layer etched in the SF₆ step.

FIGS. 6A and 6B are Scanning Electron Microscope (SEM) images of the SiN etched at 10° C. and −50° C., imaged at 30° tilt, showing areas protected by photoresist, the sidewall of the etch, and the etched surface.

FIGS. 6C and 6D are atomic force microscope (AFM) profile of the silicon nitride (film 1) etched for 60 cycles at 10° C. and −50° C. for 5, 15, and 30 s SF₆ step time. The AFM profiles have a 1:1 height aspect ratio, showing an etch angle of 38 degrees at 50° C. Horizontal offsets between side wall AFMs are arbitrary, added for ease of viewing.

FIGS. 7A-7C are AFM measurement of SiN surface roughness on an area protected by photoresist (FIG. 7A), etched by the 60 ALE cycles at 10° C. (FIG. 7B), and at −50° C. (FIG. 7C).

FIG. 8. Flowchart illustrating a method of atomic layer etching.

FIG. 9. Example Hardware environment.

FIG. 10. Example Network Environment.

FIG. 11. Example Substrate manufactured according to one or more embodiments.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

### 1. Example Process

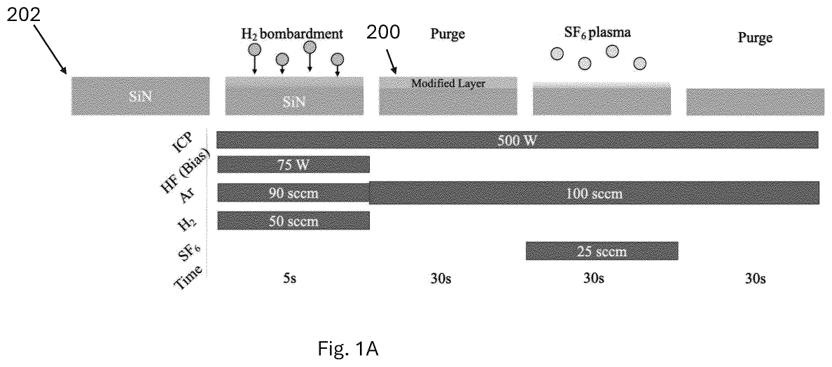

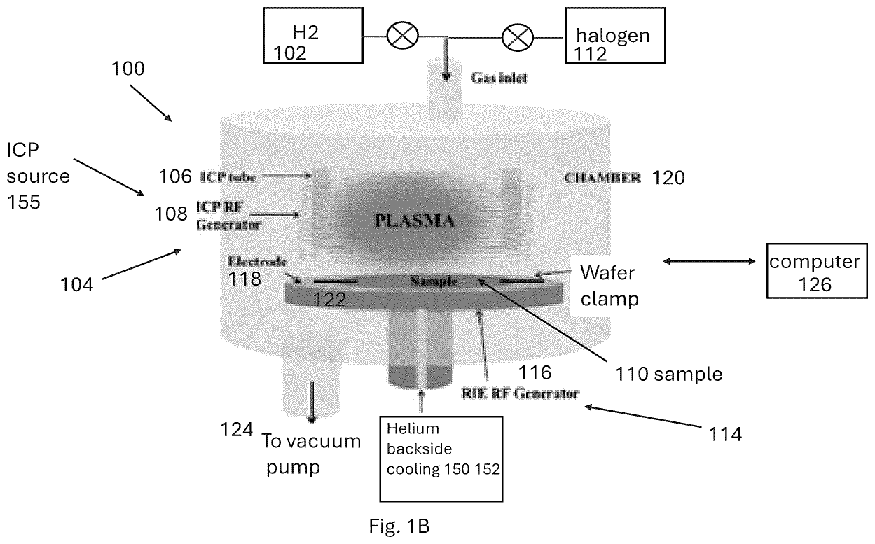

FIG. 1 illustrates a method of etching a substrate using atomic layer etching, e.g., for patterning or smoothing device structures in the silicon nitride. The method comprises obtaining a cleaned substrate which may in some embodiments be covered with a patterned resist layer exposing regions of the silicon nitride to be etched; and followed by processing (e.g., etching) the (e.g., exposed) regions using the atomic layer etching. FIG. 1 illustrates the etching comprises, in step 1, exposing the silicon nitride to a reactant that combines with the silicon nitride to form a compound in a modified layer, purging the reactor using an inert gas such as, but not limited to, argon (step 2); removing the modified layer using a removal agent, wherein the modified layer is removed at a higher rate than the silicon nitride (step 3); and purging the reactor using an inert gas (step 4).

In one embodiment, step 1 forming the modified layer comprises a proton exchange process, e.g., bombarding the silicon nitride with a hydrogen and plasma comprising protons accelerated by a bias in an ALE reactor, to form the modified layer on the silicon nitride substrate.

Atomic layer etching can be performed in self-limiting cycles rather than continuously for increased control of dimensions and or smoothness. Increased precision in the dimensions of the waveguides in optical circuits facilitates device performance. Increased smoothness decreases scattering loss in waveguides or other optical components. Improved geometry allows for steeper sidewalls and less micro-trenching which can lead to improved waveguide confinement.

### 2. Example Reactor

FIG. 1b illustrates an ALE apparatus or tool 100 comprising a source of a reactant gas 102 (e.g., hydrogen); and a plasma source 104 or a source of a first field (e.g., an inductively coupled plasma ((ICP) source comprising ICP tube 106 and ICP radio frequency (RF) generator 108) for ionizing the reactant gas to form a plasma for reacting with a surface of a substrate 110 (comprising silicon nitride) to form a modified layer on the substrate. The tool further comprises a source of a treatment 112 (e.g., gas comprising halogen such as chlorine or fluorine or bromine or iodine) for removing the modified layer; and a source of a second field 114 (e.g., RF generator 116 and electrode 118) for accelerating ions in the plasma or treatment towards the substrate; a reaction chamber 120; a temperature stage 122 for controlling a temperature of the substrate; and a vacuum pump 124 for controlling purging and pressure within the reaction chamber.

The tool further comprises a computer 126 comprising a non-transitory computer readable medium storing a plurality of instructions for controlling the atomic layer etching using the tool. The plurality of instructions comprise outputting the reactant in a first cycle to form the modified layer, outputting the treatment to remove the modified layer in a second cycle so as to etch and/or smooth features in the silicon nitride; controlling the number of cycles, the temperature, pressure, an energy of the plasma or the ions incident on the substrate; and a dose of the reactant and the treatment.

### 2. Example Results

### A. Material

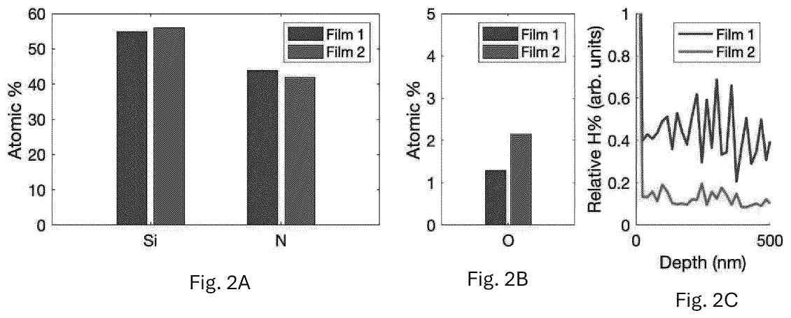

The etching characteristics of two different films of silicon rich silicon nitride films, referred to as film 1 and film 2, and grown by low pressure chemical vapor deposition (LPCVD) on silicon substrates, were investigated. The two recipes used different proportions of dichlorosilane and ammonia gas to produce different atomic ratios of silicon, nitrogen, and hydrogen in the films, which in turn resulted in different levels of stress and slightly different etch characteristics. FIG. 2a, b shows X-ray photoelectron spectroscopy (XPS) data, showing the atomic ratio to be roughly Si0.55N0.45, with <3 at % Oxygen, and shows that film 1 had slightly higher nitrogen content, while film 2 had slightly higher Si content. Hydrogen forward scattering (HFS) measurements show <1 at % of hydrogen in the films, and Secondary Ion Mass Spectroscopy (SIMS) in FIG. 2c shows that film 1 had three times as much hydrogen as film 2.

### B. Processing

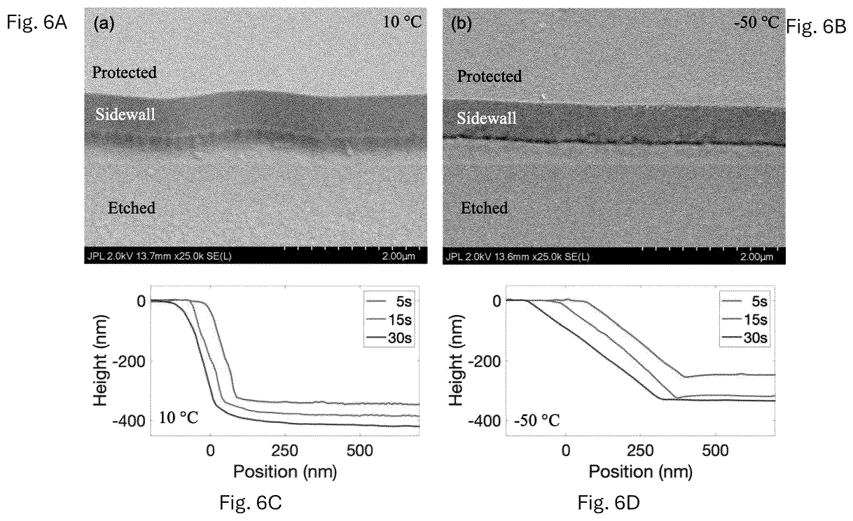

The silicon nitride films were etched in an Oxford PlasmaPro 100 Cobra ICP RIE etcher, which has both capacitively and inductively coupled plasmas, as well as a liquid nitrogen cooled stage to characterize the etch recipe at various sample temperatures. The ALE process and details of the recipe are shown in FIG. 1. Throughout the etch process, the plasma was maintained by 500 W ICP power, and a high flow of Ar gas at 20 mT. During the hydrogen bombardment step, there was an additional flow of 50 sccm of H₂, and the vertical RF field is applied for 5 seconds at 75 W, except for FIG. 6 where these parameters were varied. During the SF₆ plasma step, there was no applied RF, only the addition of 25 sccm SF₆ gas for 30 s unless otherwise noted. Each step was followed by a 30 s purge step with only Ar gas, with plasma maintained by the ICP.

The silicon nitride wafers were coated by AZ 5214 photoresist, and patterned by photolithography. The wafers were then cleaved into chips, fixed on a silicon carrier wafer using fomblin oil, and etched. The chips were etched by at least 30 cycles of the ALE process to obtain an average etch depth per cycle over many cycles. After etching, the resist was stripped by sonication in acetone. Before each process, the plasma chamber was cleaned by an Ar plasma clean recipe on a blank silicon wafer to ensure the chamber condition was consistent between runs.

### C. Characterization

The etch depth of the silicon nitride films was characterized by a profilometer, comparing the difference in height between the etched and protected areas of the film. The surface roughness of the etched material was measured by non-contact mode atomic force microscopy (AFM), and the side walls of the etch were characterized by AFM and scanning electron microscopy (SEM). The Si, C and O composition of the films was determined by XPS, and the relative H content between the films was determined by SIMS, using OH⁻ as a proxy for the hydrogen content, and normalizing by the O⁻ content of the films. HFS was performed by Eurofins EAG Laboratories as a calibration for the overall at % of H.

### 1. Synergy

The silicon nitride ALE recipe includes alternating steps of surface modification and removal. In order to test the interaction between the steps of an ALE recipe, it is common to perform a “synergy test”, in which individual steps of the etch recipe are run alone. We performed this test by processing the silicon nitride using only the H₂ surface modification and purge steps, or only the SF₆ plasma surface removal and purge steps. The synergy value, S %, as defined by equation 1, quantitatively compares the etch depth using only individual steps of the ALE cycle to the etching done by the full etch cycle. An etch process where the etching can be performed by only one step without needing the other will lead to a low synergy value.

$$S \% = 1 - ( \frac{{E}_{{H}_{2}} + {E}_{{SF}_{6}}}{{E}_{Cycle}} )$$

Equation 1: Synergy percentage of an ALE recipe. E_{H2′} is the etch depth of the H₂ step alone, E_{SF6} is the etch depth of the pristine silicon nitride without H₂ plasma modification, and Ecycle is the etch depth of the full ALE cycle.

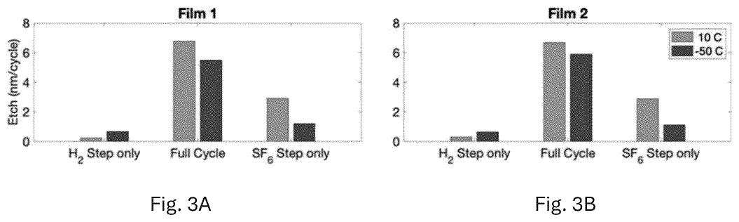

FIG. 3 shows the resulting etch depths from the individual steps compared to the full cycle. There is a small amount of etching done in the H₂ step, which is likely due to physical sputtering of the material in the presence of the plasma with the vertical bias field applied. There was a significantly larger etch depth during the SF₆ step alone, which could be attributed to spontaneous SF₆ etching of the silicon-rich film. Given that there is no vertical bias field in this step, this etch is isotropic, which may be nonideal for certain applications. However, we observed that when the wafer temperature was lowered from 10° C. to −50° C., the spontaneous etching by the fluorinated plasma was significantly reduced. At 10° C., the synergy value, S %, was 52% and 53% for the two films of silicon nitride, and improved to 66% and 70% at −50 C.

### 2. SF₆ Step Saturation

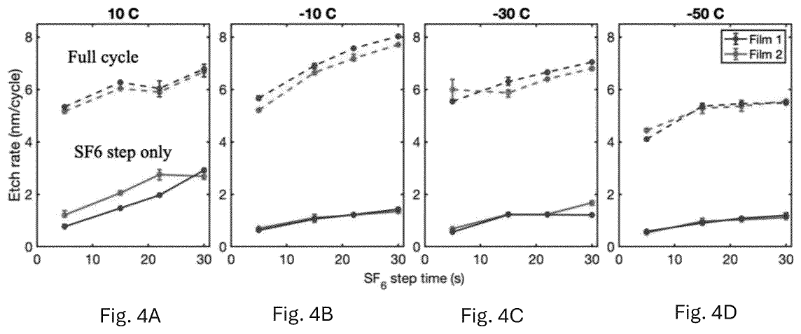

In order to test the etch saturation SF₆ step, we varied the length of the SF₆ exposure as at different temperatures. We performed these etches both including the H₂ surface modification step and without the H₂ modification, etching the pristine silicon nitride. FIG. 4 shows the etch rate as a function of SF₆ step time at various temperatures. At all temperatures, we found that the H₂ modified silicon nitride etches significantly faster than the unmodified surface. However, at 10° C., we observed that the SF₆ step continues to etch the material as this step time is increased, and we did not observe saturation behavior of the etch. This indicates that in the full atomic layer etch recipe, the silicon nitride continues to be etched by the SF₆, even past surface modified level. As we reduced the temperature of the wafer, we found that the etch per cycle of both the modified and pristine SiN reduces significantly. Additionally, we observed that the etch per cycle of the full ALE recipe saturates, indicating that the reduced temperature reduces the spontaneous etching of the unmodified SiN by the SF₆ plasma. This self-limiting aspect of the etch process greatly increases the ability to precisely control etch depth.

### 3. H₂ Step Saturation

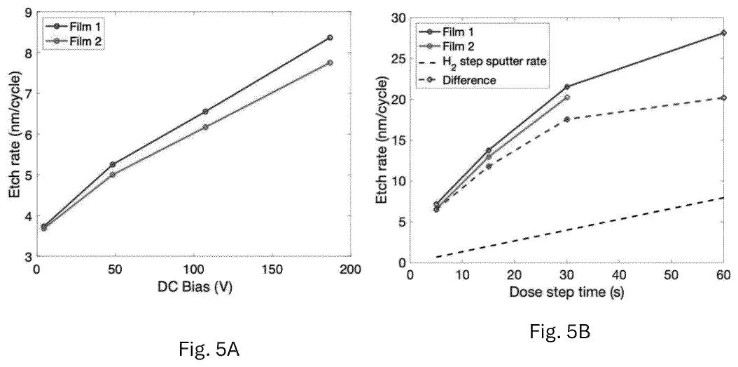

In order to test the hydrogen implantation depth of the surface modification layer, we performed the etch with varying RF power during the H₂ plasma step, shown in FIG. 5a. As the vertical electric field was increased, hydrogen ions were able to penetrate further into the silicon nitride, allowing for increased thickness of the surface modified layer. We observed a roughly linear relationship between the DC bias in the surface modification step and the overall etch rate of an ALE cycle indicating that the bias power in the H₂ step can be a valuable control in applications needing a small, precise etch depth. FIG. 5b, shows the etch depth as a function of time of the H₂ plasma step, where we observed an increase in the etch depth per cycle with increasing H₂ dose time. This increase in etch depth comes from two sources. The first is the increased amount of material that is physically sputtered off of the film in this H₂ plasma step, which is determined by measuring the etch rate of the H₂ dose step without the SF₆ step. The remaining increase in etch depth comes from the increased depth of the surface modified layer, shown by the blue dashed line in FIG. 5(b). We found that the thickness of the surface modified layer saturates at 20 nm, twice as thick as other reports.^{21,22} These results show that the H₂ step conditions can be tuned to control etch depth per cycle, which are important for precise control of total etch depth.

### 4. Sidewall Profile and Surface Roughness

Finally, and for some applications most importantly, we found that the sidewall profile was significantly improved by the reduced etching temperature in terms of side wall homogeneity. FIGS. 6(a,b) shows SEM images of the silicon nitride etched at 10° C. and −50° C. At 10° C., the image of the sidewall shows a rounded edge at the bottom, while the sample etched at −50° C. shows a sharper bottom edge, and a flatter etched surface. FIGS. 6(c,d) show AFM topography of the sidewall, etched for 60 cycles at 10° C. and −50° C., for different SF₆ step times. At 10° C., the bottom of the etch profile is curved, indicating the presence of isotropic etching. When comparing the different SF₆ etch times at this temperature, we also observe that the etch does not fully saturate, and there is continued etching of the material with increasing SF₆ plasma exposure. For the sample etched at −50° C., the sidewall device shows no curve, indicating a reduction of isotropic etching, and showing the enhancement of the side wall homogeneity.

Additionally, we observed very little difference in the etch depth between the sample with a 15 and 30 s SF₆ step length, indicating a higher degree of etch saturation, confirming the results from FIG. 4. Such control of sidewall profile is highly valuable for optical waveguides fabricated in SiN, where light scattering off of sidewall roughness can lead to a source of optical loss.^{14,15}

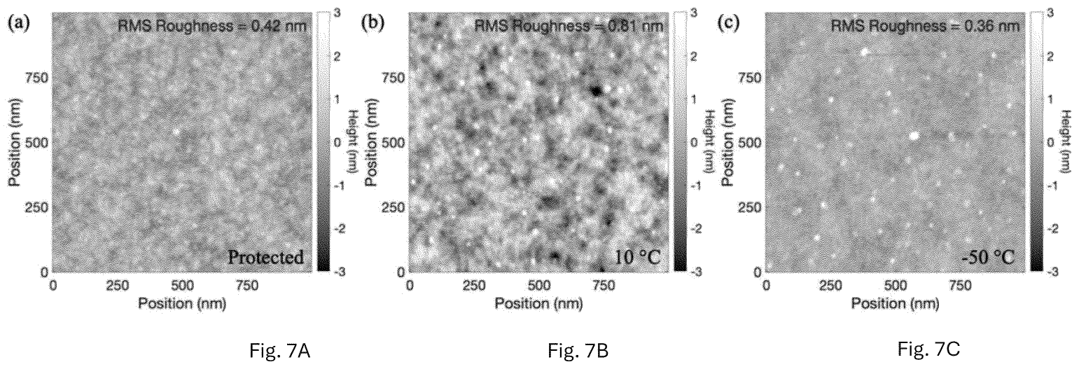

In addition to the improvement in side-wall homogeneity, we also observed a decrease in the surface roughness of the etched silicon nitride at −50° C. FIG. 7(a) shows AFM scans of the surface of the silicon nitride protected during the etch by the photoresist, giving the initial surface roughness. FIG. 7(b,c) shows the AFM of the surface after 60 cycles of etch at 10° C. and −50° C. In this figure, we observe that the etching at reduced temperature decreases the RMS surface roughness of the material from 0.42 to 0.36 nm, while etching at 10° C. increases the surface roughness to 0.81 nm. This reduction is surface roughness indicates a reduction in spontaneous etch processes, which could have varied etch rates at the microscopic level due to local differences in plasma or surface composition. Decreased surface roughness is also useful for waveguides with tight optical confinement, where scattering off surface defects can lead to a significant source of loss.

### Process Steps

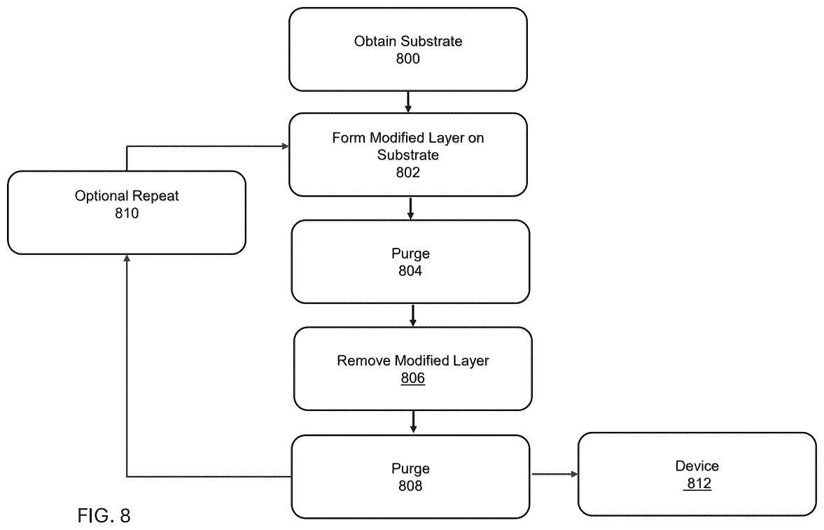

FIG. 8 illustrates a method of atomic layer etching comprising the following steps.

Block 800 represents obtaining a substrate in an atomic layer etching reactor.

Block 802 represents forming a modified layer (e.g., damaged layer) on the substrate using first reactants. In some embodiments, the first reactants comprise ionic species comprising at least one of argon or a halogen/halide (e.g., chlorine or fluorine containing species or molecule), or hydrogen. In some embodiments, the energy of the ionic species is controlled via application of a bias voltage, e.g., from an RF or ICP source. In some embodiments, the halide and/or hydrogen reacts with the substate material to form the modified layer. In some embodiments, the temperature is reduced to a level to prevent halogen (e.g., chlorine) radicals becoming so reactive that they spontaneously etch the substate without formation of the modified layer as would otherwise occur at room temperature. In some embodiments, the halogen comprising chlorine forms chlorinated silicon nitride or species comprising silicon tetrachloride.

Block 804 represents purging the reactor (e.g., of the hydrogen) and optionally switching of the bias voltage.

Block 806 represents at least partially removing the modified layer using the second reactants comprising ionic species comprising at least one of argon, a halogen or a halide that perform chemically enhanced sputtering, e.g., with the bias voltage switched off or reduced to sufficiently low levels. In typical embodiments, the temperature is maintained at the level set in Block 802 that is selected to eliminate or prevent spontaneous etching but allows the chemically enhanced sputtering to selectively remove the modified layer over the underlying substrate. In some embodiments, the angle of incidence of the ionic species is controlled to control the etch profile.

Block 808 represents purging the reactor.

Block 810 represents optionally repeating at least steps 802-808 or steps 802 and 806.

Block 812 represents the end result, a device.

The temperature during steps 802 and 806 can be controlled to tune a profile of the etched features, etch rates, selectivity of the removal, and surface roughness in concert, as a function of the composition of the reactants and substrate. For example, independent control of the rate at which the damaged material is removed in step 806 (using temperature), can allow more precise and independent control (and wider ranges for) the etching angle, etch depth, and/or surface roughness.

For example, some etch profiles may require more vertical (e.g., 90 degree) sidewalls, some may require more trapezoidal profiles, and some processes may require initial fast etches to deeper etch depths (e.g., 500 nm) followed by more refined (less than nm per cycle) afterwards. In other examples, the etch depth and rate of removal must be controlled because if removal rate or damage layer is too thick or high, the final surface with be too rough.

For some materials, such as silicon nitride, it was unexpectedly discovered the underlying pristine substrate material was undesirably removed at a similar rate (or at a rate 10 times or less as compared) to damaged layer/modified layer in some reactors at room temperature, whereas reducing the temperature (e.g., to less than −50 degrees Celsius) suppressed the rate of removal of the underlying pristine substrate material more significantly as compared to the removal modified layer.

In this regard, a surprising result was discovered that there is a temperature influenced effect on the activation energy for removal of the pristine substrate and the modified layer, and the relative rate (ratio) could be controlled via temperature. Although reaction rate of the removal of the modified layer is also reduced with lower temperature, the reaction rate for removal of the pristine substrate reduced more significantly (e.g., infinitely smaller, to zero or insignificant levels, so that it could be frozen out).

However, in some embodiments, temperature affects the formation of the modified layer. The temperature should be selected ideally so that a constant temperature can be maintained throughout the cycle, for both steps 802 and 806 to avoid additional modification of the temperature. Thus, in some embodiments, the temperature is tailored in a range optimized for both steps 802 and 806.

For example, in one embodiment using reactants comprising ionic species comprising at least one of argon or a halide, and/or hydrogen are used to form modified layer on the substrate comprising silicon nitride. The ionic argon species is used to break up the substrate material and/or the ionic halide and/or hydrogen species reacts with substrate to form the modified layer. In some embodiments, the hydrogen diffuses to prevent reformation of the pristine substrate. It was unexpectedly discovered that the impact of hydrogen reactivity or catalytic action on formation of the modified layer was significantly impacted by the temperature. At room temperature, the amount of damage resulting in formation of the modified layer by ionic species is controlled by ion energy and the presence of hydrogen, but no modified layer was formed in the absence of hydrogen. However, at lower temperature, the modified layer was formed by the ions even without hydrogen (alternatively, the damage layer thickness was double or 5 times thicker at lower temperature below −50 degrees Celsius without hydrogen).

In some embodiments, the reactor comprises an inductively coupled plasma (ICP reactor) using bias power (to control ion energy) and ICP power (to control plasma density). It was discovered that positive bias voltages exist even when the ICP is not generating the ions and is merely being used to control plasma density (ICP power only). Such residual bias voltages (self bias, even as low as 20 eV) can be too high for selective removal of the modified layer, for some substrate materials (this may not be an issue for reactors where the ions are generated remotely and self bias in the ICP can be zero).

In some embodiments, temperature is selected to suppress or eliminate thermally activated spontaneous etching of the substrate (which may, in some situations, occur without/in the absence of formation of a modified layer e.g., by the first reactants during the modified layer formation step 802) while not undesirably suppressing chemically enhanced sputtering using the second reactants removing the modified layer in removal step 806 In some embodiments, the temperature may be selected to control an interplay of etches.

In some embodiments, temperature is selected to balance between reactivity and selectivity of the reactants during one or more of the steps.

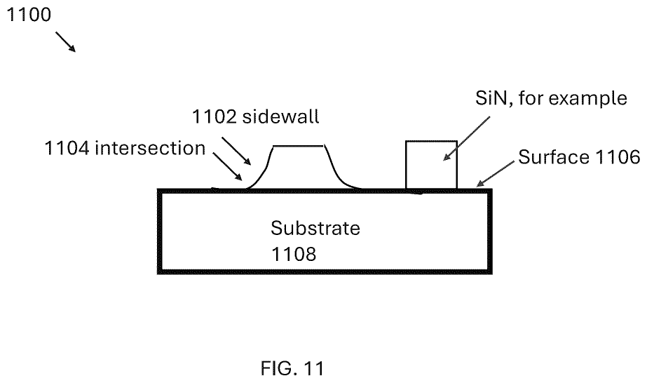

Example embodiments include, but are not limited to, the following (referring to FIGS. 1-11).

1. A method of etching, comprising:
etching a substrate using atomic layer etching at a cryogenic temperature below-50 degrees celsius.

2. The method of embodiment 1, wherein the substrate comprises silicon nitride.

3. The method of embodiment 2, wherein the etching comprises patterning a photonic integrated circuit or one or more device structures in the silicon nitride and/or smoothing the surface of one or more device structures that have been patterned by another process.

4. The method of embodiment 1 or 2, wherein the etching comprises performing the following steps at the cryogenic temperature:
(a) exposing the silicon nitride to a hydrogen plasma comprising protons accelerated by a bias in an ALE reactor, to form a modified layer on the lithium niobate substrate;
(b) purging the reactor using an inert gas;
(c) removing the modified layer using a removal agent at a pressure below 100 mT; and
(d) purging the reactor using an inert gas.

5. The method of any of the embodiments 1-4, wherein the removing comprises sputtering using chemical species or using ions accelerated by a bias under conditions that remove the modified layer over the bulk silicon nitride in a self-limiting process.

6. The method of any of the embodiments 1-4, wherein the removing comprises exposing the modified layer to the removal agent comprising chlorine or fluorine as a neutral species or in a plasma as an ionic species accelerated by a bias.

7. A device comprising:
silicon nitride film on a silicon substrate, the silicon nitride having a surface roughness less than 0.36 nm over and area of 1000 nanometers (nm) by 1000 nm and homogeneous sidewalls (uniform angle with respect to vertical to within 1 percent).

8. The device of embodiment 7 comprising a waveguide wherein the silicon nitride is a cladding layer in the waveguide comprising silicon, wherein the waveguide has a sidewall inclined at a sharp non rounded angle.

9. An atomic layer etching apparatus 100:
a source 102 of a reactant for reacting with a surface of a substrate so as to form a modified layer 200 on the substrate 202, wherein the reactant is generated by a plasma, and the substrate;
a refrigerant 150 coupled to a low temperature stage 122 for supporting the substrate 110 at a temperature below-50 degrees Celsius;
a source 112 of a treatment for removing the modified layer; and
a computer 126, 900 comprising a non-transitory computer readable medium storing a plurality of instructions, the plurality of instructions comprising:
outputting the reactant in the reactor tool,
outputting the treatment to remove the modified layer so as to etch and/or smooth features in the substrate.

10. A method of etching, comprising:
etching a substrate using atomic layer etching comprising using one or first reactants to form a modified layer on the substrate and one or more second reactants to remove the modified layer from the substrate, comprising:
selecting a temperature of the atomic layer etching as a function of at least one of a composition of a material of the substrate, a composition of the modified layer, a composition of the reactants, a bias voltage present during the etching, and optionally composition of a masking material on the substrate, and at least one of a desired profile, desired etch depth, desired etch rate, or desired roughness achieved by the etching.

11. The method of embodiment 10, wherein the temperature suppresses a rate of removal of the (unmodified) material of the substrate as compared to a rate of removal of the modified layer using the second reactants.

12. The method of embodiment 10 or 11, wherein the temperature suppresses the rate of removal of the unmodified material layer by exponentially more, a nonlinear factor, at least an order of magnitude, or a factor greater than 2, as compared to the rate of removal of the modified layer.

13. The method of any of the embodiments 10-12, wherein the temperature suppresses the rate of removal of the material of the substrate to zero by increasing the activation energy for removal of the material of the substrate as compared to the activation energy for removal of the modified layer, such that the modified layer is selectively removed over the pristine substate material.

14. The method of any of the embodiments 10-13, wherein the temperature is cryogenic temperature below-50 degrees Celsius.

15. The method of any of the embodiments 10-14, wherein the profile is an angle of sidewalls between 45 degrees and 90 degrees or a trapezoidal profile and the desired etch rate is 6 nanometers or less removed per cycle.

16. The method of any of the embodiment 10-15, wherein atomic layer etching in a reactor comprises one or more cycles each comprising:
using the first reactants to form the modified layer;
purging at least some of the first reactants from the reactor and removing a bias voltage; and
removing the modified layer using the second reactants;

17. The method of embodiment 16, wherein the reactor includes an Inductively Coupled Plasma source for generating the second reactants and the first reactants comprising ions, wherein the bias voltage is used to control an energy of the ions and a power of the ICP source controls a plasma density of the ions.

18. The method of embodiment 17, wherein the temperature suppresses the energy of the ions to counteract a residual or undesirable level of the bias voltage (self bias) applied using the ICP source.

19. The method of any of the embodiments, wherein the first reactants comprise at least one of an ionic species comprising argon or a halide (comprising a chlorine or fluorine or bromine species for halogenating the substrate to form the modified layer comprising a halide) or hydrogen and the second reactants comprise at least one of the ionic species comprising the halide or the argon removing the modified layer using chemically enhanced sputtering.

20. The method of embodiment 19, wherein the argon breaks up a surface of the substrate, the halide forms the modified layer, and the hydrogen diffuses to prevent reformation of the substrate prior to formation of the modified layer.

21. The method of any of the embodiments, wherein the temperature is selected as a function of an amount of the first reactants comprising hydrogen, wherein the temperature is reduced so that the modified layer is formed (and a thickness of the modified layer is increased) even at lower concentrations of hydrogen, as compared to room temperature.

22. The method of any of the embodiments, wherein the material of the substrate is silicon nitride

23. The method of any of the embodiments, wherein the temperature is selected to suppress or eliminate thermally activated spontaneous etching of the substrate without formation of a modified layer while not undesirably suppressing chemically enhanced sputtering using the second reactants removing the modified layer.

24. The method of any of the embodiments 10-23, wherein the first reactant is a H₂ plasma and the second reactant is or comprises SF₆.

25. An atomic layer etching reactor 100, comprising:
one or more sources 102, 112 of first reactants and second reactants including an inductively coupled plasma source 106, 108 for generating the reactants comprising ions using a bias voltage and a power;
a cooler 152 or cooling system coupled to a temperature stage 122 for controlling a temperature of a substrate 110 mounted on the stage;
a computer 126, 900 comprising a non-transitory computer readable medium storing a plurality of instructions, the plurality of instructions comprising:
receiving as an input at least one of a desired profile, desired etch depth, desired etch rate, or desired roughness to be performed using the atomic layer etching;
receiving as inputs a composition of the material of a substrate, a composition of the reactants, a composition of a modified layer formed using the first reactants, and a composition of a masking layer deposited on the substrate;
setting a temperature of the atomic layer etching as a function of the composition of a material of the substrate, the composition of the modified layer, the composition of the reactants, the bias voltage present during the etching, the composition of a masking material on the substrate, and the at least one of a desired profile, desired etch depth, desired etch rate, or desired roughness;
outputting the first reactant to the substrate reacting with a material of the substrate to form a modified layer,
purging at least some of the reactants from the reactor; and
outputting the second reactants to remove the modified layer using chemically enhanced sputtering so as to etch and/or smooth features in the substrate.

26. The reactor of embodiment 25, wherein the cooler comprises a refrigerant for cooling the temperature below-50 degrees Celsius.

27. A method of etching, the method comprising:
cooling a substrate from a first temperature to a second temperature, wherein the substrate comprises a material;
reacting one or more first reactants with the material of the substrate to form a modified layer; and
removing the modified layer from the substrate at the second temperature using one or more second reactants to form an etched substrate, wherein:
   the substrate is at the second temperature, and
   removing the modified layer with the substrate at the second temperature is characterized by a lower rate of isotropic etching of the modified layer than with the substrate at the first temperature.

28. The method of embodiment 27, wherein the second temperature is in a range from −90° C. to −30° C.

29. The method of any of the embodiments 27-28, wherein reacting the one or more first reactants with the substrate is at a pressure in a range from 10 mT to 100 mT.

30. The method of any of the embodiments 27-29, wherein:
removing the modified layer with the substrate at the second temperature is characterized by a rate of sputtering within 10% of the rate of sputtering of the modified layer with the substrate at the first temperature.

31. The method of any of the embodiments 27-30, wherein:
removing the modified layer with the substrate at the second temperature is characterized by a lower rate of etching of the material of the substrate than with the substrate at the first temperature

32. The method of any of the embodiments 27-31, wherein:
the etched substrate comprises a sidewall profile, and the sidewall profile intersects with a surface with a radius of curvature in a range from 0 nm to 1 nm or 1 nm to 10 nm.

33. The method of any of the embodiments 27-32, wherein the etched substrate is characterized by a surface roughness in a range from 0.1 to 0.3 nm or 0.3 to 0.5 nm.

34. The method of any of the embodiments 27-33, wherein:
reacting the one or more first reactants with the material of the substrate with the substrate at the second temperature is characterized by an etching rate of the material that is less than an etching rate of the material when the substrate is at the first temperature, and
the first temperature is in a range of 10° C. to 25° C.

35. The method of any of the embodiments 27-34, wherein:
a removal rate of the material of the substrate with the substrate at the second temperature is reduced by a greater percentage than a removal rate of the modified layer with the substrate at the second temperature as compared to the substrate at the second temperature.

36. The method of any of the embodiments 27-35, further comprising a plurality of cycles of reacting the one or more first reactants and removing the modified layer using one or more second reactants.

37. The method of any of the embodiments 27-36, wherein:
the one or more first reactants comprise a hydrogen-containing compound, and
the one or more second reactants comprise a fluorine-containing compound.

38. The method of any of the embodiments 27-37, wherein:
the material comprises silicon nitride,
the one or more first reactants comprise H₂, and
the one or more second reactants comprise SF₆.

39. The method of any of the embodiments 27-38, further comprising selecting the second temperature and/or the first temperature of the atomic layer etching as a function of a composition of the material of the substrate, a composition of the modified layer, a composition of the reactants, a bias voltage present during the etching, and at least one of a desired profile, desired etch depth, desired etch rate, or desired roughness achieved by the etching

40. An etched substrate formed by the method of any of the embodiments 1-6, 10-24, or 27-39.

41. An atomic layer etching reactor 100 comprising:
a first reactant source 102;
a second reactant source 112;
an inductively coupled plasma source 155;
a cooler 152 coupled to a temperature stage 122, wherein the cooler is configured to control a temperature of a substrate 110 mounted on the temperature stage;
a substrate handling system; and
a computer 126, 900 comprising a non-transitory computer readable medium storing a plurality of instructions, the plurality of instructions comprising:
   transferring a substrate to the temperature stage using the substrate handling system,
   setting a temperature of the temperature stage to a temperature, wherein setting the temperature uses the cooler,
   flowing one or more first gases from the first reactant source through the inductively coupled plasma source to form one or more first reactants,
   reacting the one or more first reactants with a material of the substrate to form a modified layer,
   flowing one or more second gases from the second reactant source through the inductively coupled plasma source to form one or more second reactants,
   removing the modified layer from the substrate at the temperature using the one or more second reactants to form an etched substrate, and
   removing the etched substrate from the temperature stage using the substrate handling system.

42. The atomic layer etching reactor of embodiment 41, wherein the cooler comprises a refrigerant for cooling the temperature below −50° C.

43. The reactor of embodiment 41, 42 or 43, wherein the instructions include selecting a temperature of the atomic layer etching as a function of a composition of a material of the substrate, a composition of the modified layer, a composition of the reactants, a bias voltage present during the etching, and at least one of a desired profile, desired etch depth, desired etch rate, or desired roughness achieved by the etching.

44. The reactor of any of the embodiments 41-43, wherein the temperature suppresses the rate of removal of the material of the substrate by increasing the activation energy for removal of the material of the substrate as compared to the activation energy for removal of the modified layer, such that the modified layer is selectively removed over the pristine substate material.

45. The reactor of any of the embodiments 41-44, wherein the reactor includes an Inductively Coupled Plasma source for generating the second reactants and the first reactants comprising ions, wherein a bias voltage is used to control an energy of the ions and a power of the ICP source controls a plasma density of the ions.

46. An etched substrate 1100 comprising a silicon nitride (e.g., on a silicon substrate) wherein the etched substrate comprises a sidewall profile 1102, and the sidewall profile intersects 1104 with a surface 1106 of the substrate 1108 with a radius of curvature in a range from 0 nm to 1 nm or 1 nm to 10 nm and/or wherein the etched substrate is characterized by a surface roughness in a range from 0.1 to 0.3 nm or 0.3 to 0.5 nm and characterized by etching using atomic layer etching.

47. The device of embodiment 46 comprising a waveguide wherein the silicon nitride is a cladding layer in the waveguide comprising silicon, wherein the waveguide has a sidewall inclined at a sharp non rounded angle.

48. The method of any of the embodiments wherein the first reactant comprises a H₂ plasma to modify the surface layer of the material of the modified layer and the second reactant comprises an SF₆

49. The reactor of any of the embodiments 9, 41-45 or 25-26 configured for performing the method of any of the embodiments 1-6, 10-24, or 27-39 or forming the device of any of the embodiments 40, 7-8, or 46-47.

50. The reactor of any of the embodiments, wherein the computer comprises:
(a) one or more computers having one or more memories;
(b) one or more processors executing on the one or more computers;
(c) the one or more memories storing the one or more sets of instructions.

51. A computer readable medium storing the instructions of any of the embodiments.

### Advantages and Improvements

We have found a quasi-atomic layer etch recipe for silicon nitride that is compatible with low pressure ICP RIEs, and explored the effect of wafer temperature on the etch characteristics. We explore the etch saturation of the both the H₂ and SF₆ steps of this recipe, and find that both steps show etch saturation, in agreement with previous studies on atomic layer etching of silicon nitride.^{21,22} Furthermore, we found that reducing the temperature of the wafer during etching decreases the surface roughness of the etched material, and significantly enhances the self-limiting aspect of the SF₆ modified surface removal step, which in turn enhances the synergy of the etch. Finally, we showed that the side wall profile becomes more homogenous at reduced temperature, due to the reduction of isotropic etching by the SF₆ plasma.

Atomic layer etching has numerous advantages over reactive ion etching, including precise etch depth control,^{2,25} reduced surface roughness,^{6,17} and reduced surface damage due to the often-lower bias power used. Silicon nitride films are very commonly as a dielectric of waveguide material, with silicon-rich SiN being increasingly used for optical waveguides due to its increased index of refraction and reduced stress compared to stoichiometric SiN.⁸ For tightly confined waveguide modes in silicon nitride, sidewall roughness plays an important role in loss by scattering.^{13,14} The enhanced side wall homogeneity using cryogenic atomic layer etch will likely enable lower loss in these waveguides.

### Hardware Environment

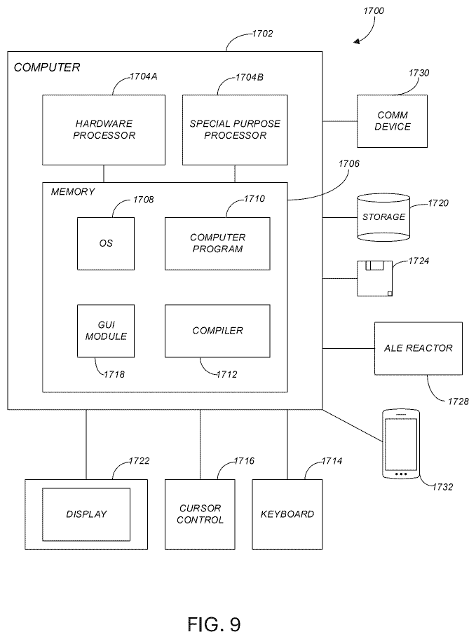

FIG. 9 is an exemplary hardware and software environment 1700 (referred to as a computer-implemented system and/or computer-implemented method) coupled to (or comprised within) a reactor 1728 used to implement one or more embodiments of the invention. The hardware and software environment includes a computer 1702 and may include peripherals. Computer 1702 may be a user/client computer, server computer, or may be a database computer. The computer 1702 comprises a hardware processor 1704A and/or a special purpose hardware processor 1704B (hereinafter alternatively collectively referred to as processor 1704) and a memory 1706, such as random access memory (RAM). The computer 1702 may be coupled to, and/or integrated with, other devices, including input/output (I/O) devices such as a keyboard 1714, a cursor control device 1716 (e.g., a mouse, a pointing device, pen and tablet, touch screen, multi-touch device, etc.). In one or more embodiments, computer 1702 may be coupled to, or may comprise, a portable or media viewing/listening device 1732 (e.g., an MP3 player, IPOD, NOOK, portable digital video player, cellular device, personal digital assistant, etc.). In yet another embodiment, the computer 1702 may comprise a multi-touch device, mobile phone, gaming system, internet enabled television, television set top box, or other internet enabled device executing on various platforms and operating systems.

In one embodiment, the computer 1702 operates by the hardware processor 1704A performing instructions defined by the computer program 1710 (e.g., a computer-controlled ALE application) under control of an operating system 1708. The computer program 1710 and/or the operating system 1708 may be stored in the memory 1706 and may interface with the user and/or other devices to accept input and commands and, based on such input and commands and the instructions defined by the computer program 1710 and operating system 1708, to provide output and results.

Output/results may be presented on the display 1722 or provided to another device for presentation or further processing or action. In one embodiment, the display 1722 comprises a liquid crystal display (LCD) having a plurality of separately addressable liquid crystals. Alternatively, the display 1722 may comprise a light emitting diode (LED) display having clusters of red, green and blue diodes driven together to form full-color pixels. Each liquid crystal or pixel of the display 1722 changes to an opaque or translucent state to form a part of the image on the display in response to the data or information generated by the processor 1704 from the application of the instructions of the computer program 1710 and/or operating system 1708 to the input and commands. The image may be provided through a graphical user interface (GUI) module 1718. Although the GUI module 1718 is depicted as a separate module, the instructions performing the GUI functions can be resident or distributed in the operating system 1708, the computer program 1710, or implemented with special purpose memory and processors. In one or more embodiments, the processor comprises an application specific integrated circuit (ASIC) or field programmable gate array (FPGA).

In one or more embodiments, the display 1722 is integrated with/into the computer 1702 and comprises a multi-touch device having a touch sensing surface (e.g., track pod or touch screen) with the ability to recognize the presence of two or more points of contact with the surface. Examples of multi-touch devices include mobile devices (e.g., IPHONE, NEXUS S, DROID devices, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 1702 according to the computer program 1710 instructions may be implemented in a special purpose processor 1704B. In this embodiment, some or all of the computer program 1710 instructions may be implemented via firmware instructions stored in a read only memory (ROM), a programmable read only memory (PROM) or flash memory within the special purpose processor 1704B or in memory 1706. The special purpose processor 1704B may also be hardwired through circuit design to perform some or all of the operations to implement the present invention. Further, the special purpose processor 1704B may be a hybrid processor, which includes dedicated circuitry for performing a subset of functions, and other circuits for performing more general functions such as responding to computer program 1710 instructions. In one embodiment, the special purpose processor 1704B is an application specific integrated circuit (ASIC), field programmable gate array.

The computer 1702 may also implement a compiler 1712 that allows an application or computer program 1710 written in a programming language such as C, C++, Assembly, SQL, PYTHON, PROLOG, MATLAB, RUBY, RAILS, HASKELL, or other language to be translated into processor 1704 readable code. Alternatively, the compiler 1712 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 1710 accesses and manipulates data accepted from I/O devices and stored in the memory 1706 of the computer 1702 using the relationships and logic that were generated using the compiler 1712.

The computer 1702 also optionally comprises an external communication device such as a modem, satellite link, Ethernet card, or other device for accepting input from, and providing output to, other computers 1702.

In one embodiment, instructions implementing the operating system 1708, the computer program 1710, and the compiler 1712 are tangibly embodied in a non-transitory computer-readable medium, e.g., data storage device 1720, which could include one or more fixed or removable data storage devices, such as a zip drive, floppy disc drive 1724, hard drive, CD-ROM drive, tape drive, etc. Further, the operating system 1708 and the computer program 1710 are comprised of computer program 1710 instructions which, when accessed, read and executed by the computer 1702, cause the computer 1702 to perform the steps necessary to implement and/or use the present invention or to load the program of instructions into a memory 1706, thus creating a special purpose data structure causing the computer 1702 to operate as a specially programmed computer executing the method steps described herein. Computer program 1710 and/or operating instructions may also be tangibly embodied in memory 1706 and/or data communications devices 1730, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 1702.

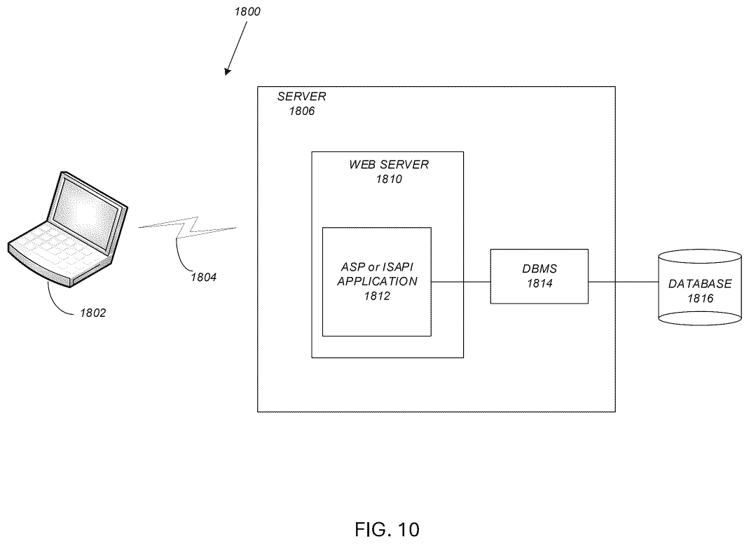

FIG. 10 schematically illustrates a typical distributed/cloud-based computer system 1800 using a network 1804 to connect client computers 1802 to server computers 1806. A typical combination of resources may include a network 1804 comprising the Internet, LANs (local area networks), WANs (wide area networks), SNA (systems network architecture) networks, or the like, clients 1802 that are personal computers or workstations (as set forth in FIG. 9), and servers 1806 that are personal computers, workstations, minicomputers, or mainframes (as set forth in FIG. 9). However, it may be noted that different networks such as a cellular network (e.g., GSM [global system for mobile communications] or otherwise), a satellite based network, or any other type of network may be used to connect clients 1802 and servers 1806 in accordance with embodiments of the invention.

A network 1804 such as the Internet connects clients 1802 to server computers 1806. Network 1804 may utilize ethernet, coaxial cable, wireless communications, radio frequency (RF), etc. to connect and provide the communication between clients 1802 and servers 1806. Further, in a cloud-based computing system, resources (e.g., storage, processors, applications, memory, infrastructure, etc.) in clients 1802 and server computers 1806 may be shared by clients 1802, server computers 1806, and users across one or more networks. Resources may be shared by multiple users and can be dynamically reallocated per demand. In this regard, cloud computing may be referred to as a model for enabling access to a shared pool of configurable computing resources. \

Clients 1802 may execute a client application or web browser and communicate with server computers 1806 executing web servers 1810. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 1802 may be downloaded from server computer 1806 to client computers 1802 and installed as a plug-in or ACTIVEX control of a web browser. Accordingly, clients 1802 may utilize ACTIVEX components/component object model (COM) or distributed COM (DCOM) components to provide a user interface on a display of client 1802. The web server 1810 is typically a program such as MICROSOFT'S INTERNET INFORMATION SERVER.

Web server 1810 may host an Active Server Page (ASP) or Internet Server Application Programming Interface (ISAPI) application 1812, which may be executing scripts. The scripts invoke objects that execute business logic (referred to as business objects). The business objects then manipulate data in database 1816 through a database management system (DBMS) 1814. Alternatively, database 1816 may be part of, or connected directly to, client 1802 instead of communicating/obtaining the information from database 1816 across network 1804. When a developer encapsulates the business functionality into objects, the system may be referred to as a component object model (COM) system. Accordingly, the scripts executing on web server 1810 (and/or application 1812) invoke COM objects that implement the business logic. Further, server 1806 may utilize MICROSOFT'S TRANSACTION SERVER (MTS) to access required data stored in database 1816 via an interface such as ADO (Active Data Objects), OLE DB (Object Linking and Embedding DataBase), or ODBC (Open DataBase Connectivity).

Generally, these components 1800-1816 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 1802 and 1806 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 1802 and 1806. Embodiments of the invention are implemented as a software/ALE application on a client 1802 or server computer 1806. Further, as described above, the client 1802 or server computer 1806 may comprise a thin client device or a portable device that has a multi-touch-based display.

### REFERENCES

The following references are incorporated by reference herein for all purposes.
¹ K. J. Kanarik, T. Lill, E. A. Hudson, S. Sriraman, S. Tan, J. Marks, V. Vahedi, and R. A. Gottscho, “Overview of atomic layer etching in the semiconductor industry,” J. Vac. Sci. Technol. A 33(2), 020802 (2015).
² W. Lu, Y. Lee, J. Murdzek, J. Gertsch, A. Vardi, L. Kong, S. M. George, and J. A. del Alamo, in 2018 IEEE Int. Electron Devices Meet. IEDM (2018), p. 39.1.1-39.1.4.
³ G. S. Oehrlein, D. Metzler, and C. Li, “Atomic Layer Etching at the Tipping Point: An Overview,” ECS J. Solid State Sci. Technol. 4(6), N5041 (2015).
⁴ S. M. George, and Y. Lee, “Prospects for Thermal Atomic Layer Etching Using Sequential, Self-Limiting Fluorination and Ligand-Exchange Reactions,” ACS Nano 10(5), 4889-4894 (2016).
⁵ H. Wang, A. Hossain, D. Catherall, and A. J. Minnich, “Isotropic plasma-thermal atomic layer etching of aluminum nitride using SF$_6$ plasma and Al(CH$_3$)$_3$,” (2022).
⁶ S. H. Gerritsen, N. J. Chittock, V. Vandalon, M. A. Verheijen, H. C. M. Knoops, W. M. M. Kessels, and A. J. M. Mackus, “Surface Smoothing by Atomic Layer Deposition and Etching for the Fabrication of Nanodevices,” ACS Appl. Nano Mater. 5(12), 18116-18126 (2022).
⁷ Y. Chen, Q. Cheng, and W. Kang, in Opt. Microlithogr. XXV (SPIE, 2012), pp. 699-712.
⁸ H. Nejadriahi, A. Friedman, R. Sharma, S. Pappert, Y. Fainman, and P. Yu, “Thermo-optic properties of silicon-rich silicon nitride for on-chip applications,” Opt. Express 28(17), 24951-24960 (2020).
⁹ A. E. Kaloyeros, Y. Pan, J. Goff, and B. Arkles, “Review-Silicon Nitride and Silicon Nitride-Rich Thin Film Technologies: State-of-the-Art Processing Technologies, Properties, and Applications,” ECS J. Solid State Sci. Technol. 9(6), 063006 (2020).
¹⁰ C. J. Krückel, A. Fülöp, T. Klintberg, J. Bengtsson, P. A. Andrekson, and V. Torres-Company, “Linear and nonlinear characterization of low-stress high-confinement silicon-rich nitride waveguides,” Opt. Express 23(20), 25827-25837 (2015).
¹¹ S. Habermehl, “Stress relaxation in Si-rich silicon nitride thin films,” J. Appl. Phys. 83(9), 4672-4677 (1998).
¹² “Pushing the limits of CMOS optical parametric amplifiers with USRN: Si7N3 above the twophoton absorption edge | Nature Communications,” (n.d.).
¹³ M. H. P. Pfeiffer, C. Herkommer, J. Liu, T. Morais, M. Zervas, M. Geiselmann, and T. J. Kippenberg, “Photonic Damascene Process for Low-Loss, High-Confinement Silicon Nitride Waveguides,” IEEE J. Sel. Top. Quantum Electron. 24(4), 1-11 (2018).
¹⁴ D. Melati, A. Melloni, and F. Morichetti, “Real photonic waveguides: guiding light through imperfections,” Adv. Opt. Photonics 6(2), 156-224 (2014).
¹⁵ F. Morichetti, A. Canciamilla, and A. Melloni, “Statistics of backscattering in optical waveguides,” Opt. Lett. 35(11), 1777-1779 (2010).
¹⁶ C. Li, D. Metzler, C. S. Lai, E. A. Hudson, and G. S. Oehrlein, “Fluorocarbon based atomic layer etching of Si3N4 and etching selectivity of SiO2 over Si3N4,” J. Vac. Sci. Technol. A 34(4), 041307 (2016).
¹⁷ Y. Ishii, K. Okuma, T. Saldana, K. Maeda, N. Negishi, and J. Manos, “Atomic layer etching of silicon nitride using cyclic process with hydrofluorocarbon chemistry,” Jpn. J. Appl. Phys. 56(6S2), 06HB07 (2017).
¹⁸ M. Wang, P. L. G. Ventzek, and A. Ranjan, “Quasiatomic layer etching of silicon oxide selective to silicon nitride in topographic structures using fluorocarbon plasmas,” J. Vac. Sci. Technol. A 35(3), 031301 (2017).
¹⁹ N. Posseme, O. Pollet, and S. Barnola, “Alternative process for thin layer etching: Application to nitride spacer etching stopping on silicon germanium,” Appl. Phys. Lett. 105(5), 051605 (2014).
²⁰ A. I. Abdulagatov, and S. M. George, “Thermal atomic layer etching of silicon nitride using an oxidation and ‘conversion etch’ mechanism,” J. Vac. Sci. Technol. A 38(2), 022607 (2020).
²¹ S. D. Sherpa, and A. Ranjan, “Quasi-atomic layer etching of silicon nitride,” J. Vac. Sci. Technol. A 35(1), 01A102 (2017).
²² S. D. Sherpa, P. L. G. Ventzek, and A. Ranjan, “Quasiatomic layer etching of silicon nitride with independent control of directionality and selectivity,” J. Vac. Sci. Technol. A 35(5), 05C310 (2017).
²³ S. D. Sherpa, and A. Ranjan, in Adv. Etch Technol. Nanopatterning VII (SPIE, 2018), pp. 29-38.
²⁴ K. Nakane, R. H. J. Vervuurt, T. Tsutsumi, N. Kobayashi, and M. Hori, “In Situ Monitoring of Surface Reactions during Atomic Layer Etching of Silicon Nitride Using Hydrogen Plasma and Fluorine Radicals,” ACS Appl. Mater. Interfaces 11(40), 37263-37269 (2019).
²⁵ W. Lu, Y. Lee, J. C. Gertsch, J. A. Murdzek, A. S. Cavanagh, L. Kong, J. A. del Alamo, and S. M. George, “In Situ Thermal Atomic Layer Etching for Sub-5 nm InGaAs Multigate MOSFETs,” Nano Lett. 19(8), 5159-5166 (2019).
[26] Plasma Pro 100 brochure. https://plasma.oxinst.com/products/ale/plasmapro-100ale?gad_source=1&gclid=EAIaIQobChMI6MuvtcP8iAMVnRKHAx1ZWRn4EAAYASAAEgK5IPD_BwE
[27] https://pubs.acs.org/doi/10.1021/acs.jpclett.8b00997
[28] D. N. Shanks et al., “Quasi-atomic layer etching of silicon nitride enhanced by low temperature,” J. of Vacuum Sci. and Tech., 41, available at https://pubs.aip.org/avs/jva/article/41/5/052601/2908463/Quasiatomic-layer-etching-of-silicon-nitride.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

The term “about” or “approximately” can mean within an acceptable error range for the particular value as determined by one of ordinary skill in the art, which will depend in part on how the value is measured or determined, i.e., the limitations of the measurement system. For example, “about” can mean within 1 or more than 1 standard deviation, per the practice in the art. Alternatively, “about” can mean a range of up to 20%, up to 10%, up to 5%, or up to 1% of a given value. Alternatively, particularly with respect to biological systems or processes, the term “about” or “approximately” can mean within an order of magnitude, within 5-fold, and more preferably within 2-fold, of a value. Where particular values are described in the application and claims, unless otherwise stated the term “about” meaning within an acceptable error range for the particular value should be assumed. The term “about” can have the meaning as commonly understood by one of ordinary skill in the art. The term “about” can refer to +10%. The term “about” can refer to +5%. Any exact number described herein may be modified with “about” or “approximately.”

Any of the methods described herein may be totally or partially performed with a computer system including one or more processors, which can be configured to perform the steps. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order that is logically possible. Additionally, portions of these steps may be used with portions of other steps from other methods. Also, all or portions of a step may be optional. Additionally, any of the steps of any of the methods can be performed with modules, units, circuits, or other means of a system for performing these steps.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

The above description of example embodiments of the present disclosure has been presented for the purposes of illustration and description and are set forth so as to provide those of ordinary skill in the art with a complete disclosure and description of how to make and use embodiments of the present disclosure. It is not intended to be exhaustive or to limit the disclosure to the precise form described nor are they intended to represent that the experiments are all or the only experiments performed. Although the disclosure has been described in some detail by way of illustration and example for purposes of clarity of understanding, it is readily apparent to those of ordinary skill in the art in light of the teachings of this disclosure that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the disclosure being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

A recitation of “a”, “an” or “the” is intended to mean “one or more” unless specifically indicated to the contrary. The use of “or” is intended to mean an “inclusive or,” and not an “exclusive or” unless specifically indicated to the contrary. Reference to a “first” component does not necessarily require that a second component be provided. Moreover, reference to a “first” or a “second” component does not limit the referenced component to a particular location unless expressly stated. The term “based on” is intended to mean “based at least in part on.”

The claims may be drafted to exclude any element which may be optional. As such, this statement is intended to serve as antecedent basis for use of such exclusive terminology as “solely”, “only”, and the like in connection with the recitation of claim elements, or the use of a “negative” limitation.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within embodiments of the present disclosure. The upper and lower limits of these smaller ranges may independently be included or excluded in the range, and each range where either, neither, or both limits are included in the smaller ranges is also encompassed within the present disclosure, subject to any specifically excluded limit in the stated range. Where the stated range includes one or both of the limits, ranges excluding either or both of those included limits are also included in the present disclosure.

All patents, patent applications, publications, and descriptions mentioned herein are hereby incorporated by reference in their entirety for all purposes as if each individual publication or patent were specifically and individually indicated to be incorporated by reference and are incorporated herein by reference to disclose and describe the methods and/or materials in connection with which the publications are cited. None is admitted to be prior art

What is claimed is:

1. A method of etching, the method comprising:
cooling a substrate from a first temperature to a second temperature, wherein the substrate comprises a material;
reacting one or more first reactants with the material of the substrate to form a modified layer; and
removing the modified layer from the substrate at the second temperature using one or more second reactants to form an etched substrate, wherein:
the substrate is at the second temperature, and
removing the modified layer with the substrate at the second temperature is characterized by a lower rate of isotropic etching of the modified layer than with the substrate at the first temperature.

2. The method of claim 1, wherein the second temperature is in a range from −90° C. to −30° C.

3. The method of claim 1, wherein reacting the one or more first reactants with the substrate is at a pressure in a range from 10 mT to 100 mT.

4. The method of claim 1, wherein:
removing the modified layer with the substrate at the second temperature is characterized by a rate of sputtering within 10% of the rate of sputtering of the modified layer with the substrate at the first temperature.

5. The method of claim 1, wherein:
removing the modified layer with the substrate at the second temperature is characterized by a lower rate of etching of the material of the substrate than with the substrate at the first temperature.

6. The method of claim 1, wherein:
the etched substrate comprises a sidewall profile, and
the sidewall profile intersects with a surface with a radius of curvature in a range from 0 nm to 1 nm or 1 nm to 10 nm.

7. The method of claim 1, wherein the etched substrate is characterized by a surface roughness in a range from 0.1 to 0.3 nm or 0.3 to 0.5 nm.

8. The method of claim 1, wherein:
reacting the one or more first reactants with the material of the substrate with the substrate at the second temperature is characterized by an etching rate of the material that is less than an etching rate of the material when the substrate is at the first temperature, and
the first temperature is in a range of 10° C. to 25° C.

9. The method of claim 1, wherein:
a removal rate of the material of the substrate with the substrate at the second temperature is reduced by a greater percentage than a removal rate of the modified layer with the substrate at the second temperature as compared to the substrate at the second temperature.

10. The method of claim 1, further comprising a plurality of cycles of reacting the one or more first reactants and removing the modified layer using one or more second reactants.

11. The method of claim 1, wherein:
the one or more first reactants comprise a hydrogen-containing compound, and
the one or more second reactants comprise a fluorine-containing compound.

12. The method of claim 1, wherein:
the material comprises silicon nitride,
the one or more first reactants comprise H₂, and
the one or more second reactants comprise SF₆.

13. The method of claim 1, further comprising selecting the second temperature and/or the first temperature of the atomic layer etching as a function of a composition of the material of the substrate, a composition of the modified layer, a composition of the reactants, a bias voltage present during the etching, and at least one of a desired profile, desired etch depth, desired etch rate, or desired roughness achieved by the etching.

14. An etched substrate formed by the method of claim 1.

15. An atomic layer etching reactor comprising:
a first reactant source;
a second reactant source;
an inductively coupled plasma source;
a cooler coupled to a temperature stage, wherein the cooler is configured to control a temperature of a substrate mounted on the temperature stage;
a substrate handling system; and
a computer comprising a non-transitory computer readable medium storing a plurality of instructions, the plurality of instructions comprising:
transferring a substrate to the temperature stage using the substrate handling system,
setting a temperature of the temperature stage to a temperature, wherein setting the temperature uses the cooler,
flowing one or more first gases from the first reactant source through the inductively coupled plasma source to form one or more first reactants,
reacting the one or more first reactants with a material of the substrate to form a modified layer,
flowing one or more second gases from the second reactant source through the inductively coupled plasma source to form one or more second reactants,
removing the modified layer from the substrate at the temperature using the one or more second reactants to form an etched substrate, and
removing the etched substrate from the temperature stage using the substrate handling system.

16. The atomic layer etching reactor of claim 15, wherein the cooler comprises a refrigerant for cooling the temperature below −50° C.

17. The reactor of claim 14, wherein the instructions include selecting a temperature of the atomic layer etching as a function of a composition of a material of the substrate, a composition of the modified layer, a composition of the reactants, a bias voltage present during the etching, and at least one of a desired profile, desired etch depth, desired etch rate, or desired roughness achieved by the etching.

18. The reactor of claim 14, wherein the temperature suppresses the rate of removal of the material of the substrate by increasing the activation energy for removal of the material of the substrate as compared to the activation energy for removal of the modified layer, such that the modified layer is selectively removed over the pristine substate material.

19. The reactor of claim 14, wherein the reactor includes an Inductively Coupled Plasma source for generating the second reactants and the first reactants comprising ions, wherein a bias voltage is used to control an energy of the ions and a power of the ICP source controls a plasma density of the ions.
